(19) United States
(12) Patent Application Publication
(10) Pub. No.: US 2013/0320177 A1
(43) Pub. Date: Dec. 5, 2013

(54) TILT ASSEMBLY FOR USE WITH A DISPLAY SCREEN

(71) Applicants: Cheng-Hong Chen, New Taipei City (TW); Dean F. Herring, Youngsville, NC (US); Brad M. Johnson, Raleigh, NC (US); Wen-Yao Nien, Zhubei City (TW); William L. Talley, Wake Forest, NC (US); Chiu-Jung Tsen, Hsinchu City (TW); Zong-Han You, New Taipei City (TW)

(72) Inventors: Cheng-Hong Chen, New Taipei City (TW); Dean F. Herring, Youngsville, NC (US); Brad M. Johnson, Raleigh, NC (US); Wen-Yao Nien, Zhubei City (TW); William L. Talley, Wake Forest, NC (US); Chiu-Jung Tsen, Hsinchu City (TW); Zong-Han You, New Taipei City (TW)

(73) Assignee: INTERNATIONAL BUSINESS MACHINES CORPORATION, Armonk, NY (US)

(21) Appl. No.: 13/482,960

(22) Filed: May 29, 2012

(51) Int. Cl. H05K 7/00; F16M 11/20

(52) U.S. Cl. 248/371

(57) ABSTRACT

A tilt assembly for a display screen is provided. The tilt assembly includes a base assembly that includes a base casing configured to engage with a proximally positioned surface and a base plate configured to cooperatively form the tilt assembly with the base casing. The base plate is configured to translate aft and fore and impart a pivot to the display screen.

### BACKGROUND

1. Field of the Invention

The present invention relates to a tilt assembly for use with a display screen, and more specifically, towards a tilt assembly for use with a display screen such as a point of sale display in which the tilt assembly may be manipulated to tilt and translate to remove a glare from the display screen.

2. Description of Related Art

Display screens are used as a user interface for many electronic systems. For example, personal computers have traditionally used a display screen to display information relevant to the user of the display screen, and may alternatively be provided with one or more touch-responsive features so that the user can also input information to the electronic system through the display screen.

Occasionally, a glare due to a proximal light or other electronic device may appear to the user as being reflected on the display screen. Display screens are typically placed in a generally upright orientation, and for these display screens in a generally upright orientation, a change in their orientation angle would usually eliminate the glare. This is because the proximal light or electronic device causing the glare was generally from a higher elevation, so the angle of incidence of light reflecting from the display screen was usually large. A slight tilt of the display screen would cause the reflected light, meaning the glare, to be reflected away from the viewer's line of sight.

However, for display screens that are not in a generally upright orientation, tilting of the display screen may not always be effective for eliminating a glare. For example, for point of sale display screens that may be orientated at an angle substantially less than an upright orientation, a tilt of the display screen would not be sufficient to remove the glare because the angle of incidence was usually small for glares produced by an overhead light or the like.

Accordingly, there is a need for a device or system that can eliminate or reduce display screen glare.

### BRIEF SUMMARY

In accordance with embodiments of the present invention, a tilt assembly for a display screen is provided. The tilt assembly includes a base assembly that includes a base casing configured to engage with a proximally positioned surface and a base plate configured to cooperatively form the tilt assembly with the base casing, The base plate is configured to translate aft and fore movement that imparts a pivot to the display screen.

In accordance with embodiments of the present invention, a tilt assembly for use with a display screen is provided. The tilt assembly includes a base assembly that includes a base casing configured to engage with a proximally positioned surface and a base plate configured to cooperatively form the tilt assembly with the base casing. The tilt assembly defines a pivot point beneath the base assembly.

In accordance with embodiments of the present invention, a tilt assembly for use with a display screen is provided. The tilt assembly includes a base assembly configured to engage with a proximally positioned surface that carries the display screen. The base assembly defines one or more aft and fore extending convex tracks that receive an anchor assembly. The anchor assembly extends from a base cover to a base plate that cooperatively forms a tilt assembly. The tilt assembly is configured to provide translation of the display screen that generally corresponds to the convex shape of the tracks. The tracks define a resilient material at each end thereof to provide dampening forces when the display screen is positioned at an end portion of the tracks.

In accordance with embodiments of the present invention, a display screen assembly is provided. The display screen assembly includes a display screen and a base assembly. The base assembly includes a base casing configured to engage with a proximally positioned surface and a base plate configured to cooperatively form a tilt assembly with the base casing and to carry the display screen. The base plate is configured to translate aft and fore movement that imparts a pivot to the display screen.

### BRIEF DESCRIPTION OF THE SEVERAL VIEWS OF THE DRAWINGS

FIG. 1 sets forth a perspective view of a display screen having a tilt assembly in accordance with embodiments of the present invention;

FIG. 2 sets forth an exploded perspective view of a tilt assembly in accordance with embodiments of the present invention;

FIG. 3A sets forth a side view of a display screen having a tilt assembly in a first position in accordance with embodiments of the present invention;

FIG. 3B sets forth a side view of a display screen having a tilt assembly in a second position in accordance with embodiments of the present invention;

FIG. 3C sets forth a side view of a display screen having a tilt assembly in a third position in accordance with embodiments of the present invention;

FIG. 4A sets forth a cross-sectional side view of a tilt assembly in the first position corresponding to the display screen in FIG. 3A in accordance with embodiments of the present invention;

FIG. 4B sets forth a cross-sectional side view of a tilt assembly in the second position corresponding to the display screen in FIG. 3B in accordance with embodiments of the present invention;

FIG. 4C sets forth a cross-sectional side view of a tilt assembly in the third position corresponding to the display screen in FIG. 3C in accordance with embodiments of the present invention; and

FIG. 5 sets forth an exploded perspective view of a tilt assembly in accordance with embodiments of the present invention.

### DETAILED DESCRIPTION

Exemplary tilt assemblies for a display screen and related display screens having a tilt assembly in accordance with embodiments of the present invention are described herein. Particularly, described herein are exemplary tilt assemblies having configured to translate aft and fore movement that also imparts a pivot to the display screen.

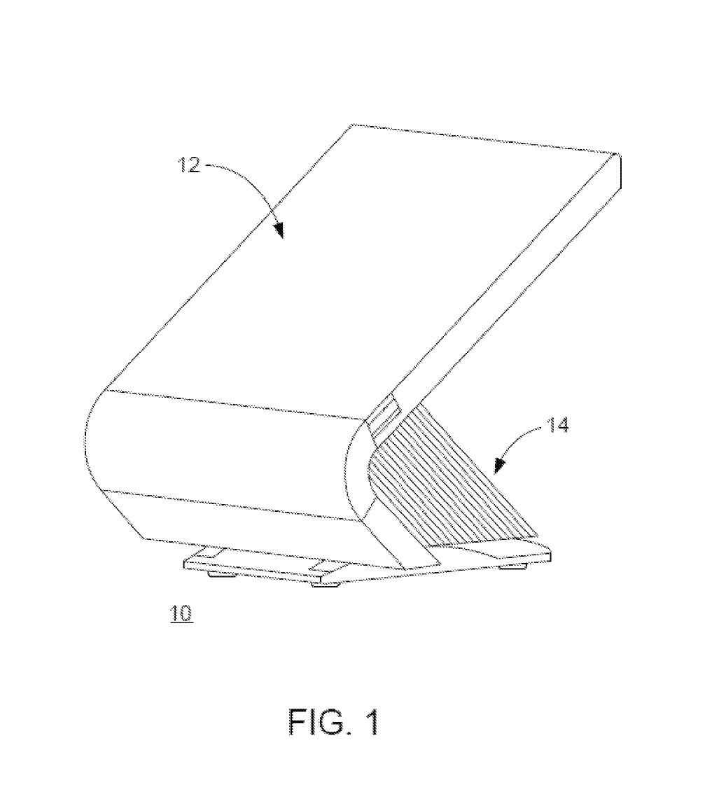

FIG. 1 illustrates a display screen assembly generally designated as 10 throughout the drawings. The display screen assembly 10 includes a display screen 12 and a tilt assembly 14. The display screen 12 is illustrated having about a 45 degree angle relative to a proximal support surface, however, the display screen 12 may have any desired orientation. The display screen 12 may be, for example, a point of sale (POS) display screen for use at, for example, a self checkout register.

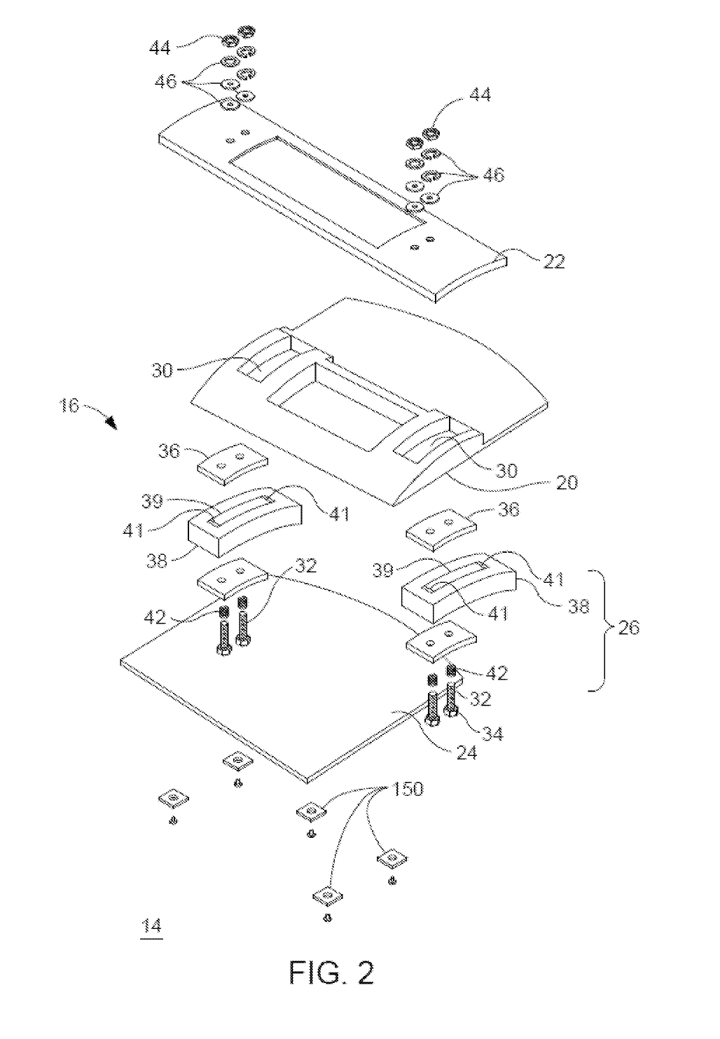

FIG. 2 illustrates an exploded view of the tilt assembly 14 for use with the display screen 12. The tilt assembly 14 generally includes a base assembly 16. The base assembly 16 includes a base casing 20. A base plate 22 is configured for slideable movement about the base casing 20. The base casing 20 and base plate 22 cooperatively form the tilt assembly 14 illustrated in FIG. 1. A bottom plate 24 is provided for forming the bottom facing surface of the base casing 20 and enclosing an anchor assembly 26. The anchor assembly 26 is configured for extending from within the base casing 20 through tracks 30 defined therein and engaging with base plate 22.

The anchor assembly 26 includes a retainer block 38 that defines a channel 39 therein. The channel 39 is configured to receive a fastener 32 that extends therethrough and into slider block 36 and further into the base plate 22. A shoulder 34 formed on the fastener 32 secures the fastener 32 against the slider block 36. One or more springs 42 may be provided to be coaxially aligned with the fastener 32 for providing dampening resistance and improving wear. A releasable fastener such as a nut 44 may be provided on an upward facing surface of the base plate 22 for receiving and engaging with the fastener 32. One or more washers 46 may be provided, and may include belleville or spring washers for further engaging the fastener 32 and providing tensioning forces thereto. One or more pads 50 may be provided on a bottom facing portion of the bottom plate 24 for providing improved traction characteristics with the proximal surface. Each of the retaining block 38 and slider block 36 may be made from a polymer having sufficient strength, yet low friction such as polyoxymethylene.

The channel 39 may include one or more materials or characteristics for providing a resistance to the fastener 32 as the fastener 32 approaches either terminal end of the channel 39. In this manner, the channel 39 may include, for example, resilient material 41 at an end thereof. Resilient material 41 may be a felt-like or other textile-based material, a polymer-based material, a spring or other biasing material, or the like. In this manner, material 41 may be provided for limiting and slowing the translation speed of the display screen 12 as it is translated fore and aft to the terminal positions of the channel 39.

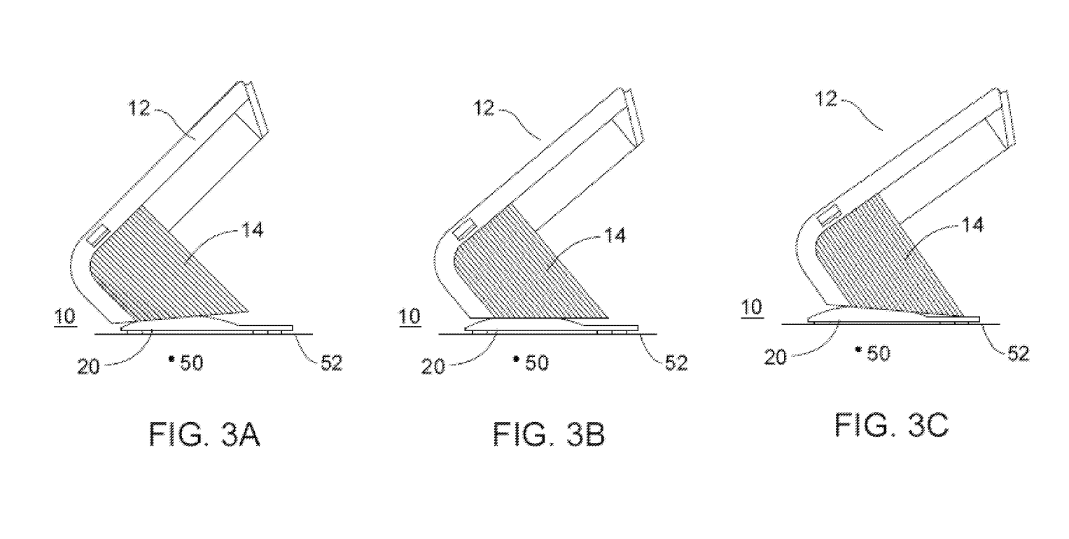

The display screen assembly 10 is illustrated in a variety of positions in each of FIG. 3A, FIG. 3B, and FIG. 3C. As illustrated in FIG. 3A, the display screen assembly 10 is shown in a first position in which the display screen 12 is tilted forward relative to the position of the display screen 12 illustrated in each of FIG. 3B and FIG. 3C. In the embodiments illustrated in FIG. 3A, the display screen 12 is tilted forward about 5 degrees relative to the position of the display screen 12 illustrated in FIG. 3B. As illustrated, the display screen 12 is also translated forwardly relative to the position of the display screen 12 illustrated in FIG. 3B. In this manner, the display screen 12 is tilted forwardly and translated forwardly in the same movement. This may be helpful for eliminating a glare that the user may otherwise see reflecting therefrom.

As illustrated in FIG. 3B, the display screen assembly 10 is shown in a second position in which the display screen 12 is tilted rearward relative to the position of the display screen 12 illustrated in FIG. 3A. In the embodiments illustrated in FIG. 3B, the display screen 12 is tilted rearward about 5 degrees relative to the display screen 12 illustrated in FIG. 3A. As illustrated, the display screen 12 is also translated rearwardly relative to the position of the display screen 12 illustrated in FIG. 3A. In this manner, the display screen 12 is tilted rearwardly and translated rearwardly with the same input from the user.

As illustrated in FIG. 3C, the display screen assembly 10 is shown in a third position in which the display screen 12 is tilted rearward relative to the position of the display screen 12 illustrated in FIG. 3B. In the embodiments illustrated in FIG. 3C, the display screen 12 is tilted rearward about 5 degrees relative to the position of the display screen 12 illustrated in FIG. 3B. As illustrated, the display screen 12 is also translated rearwardly relative to the position of the display screen 12 illustrated in FIG. 3B. In this manner, the display screen 12 is tilted and translated rearwardly with the same input from the user.

As illustrated in each of FIG. 3A, FIG. 3B, and FIG. 3C, a pivot point 50 is defined beneath the base casing 20. The pivot point 50 is defined as such due to the convex cross-section of the base casing 20 about which the base plate 22 translates about. In this manner, the bottom facing surface of the base plate 22 has a correspondingly shaped convex bottom-facing surface to match the upward-facing concave surface of the base casing 20. In accordance with embodiments disclosed herein, the pivot point 50 may be defined below a proximal surface 52 to which the base casing 20 is engaged with. The advantageous placement of the pivot point 50 below the casing 20 allows for minor adjustments to the tilt angle of the display screen 12 by providing a larger radius of movement than if the pivot point was above the surface 52.

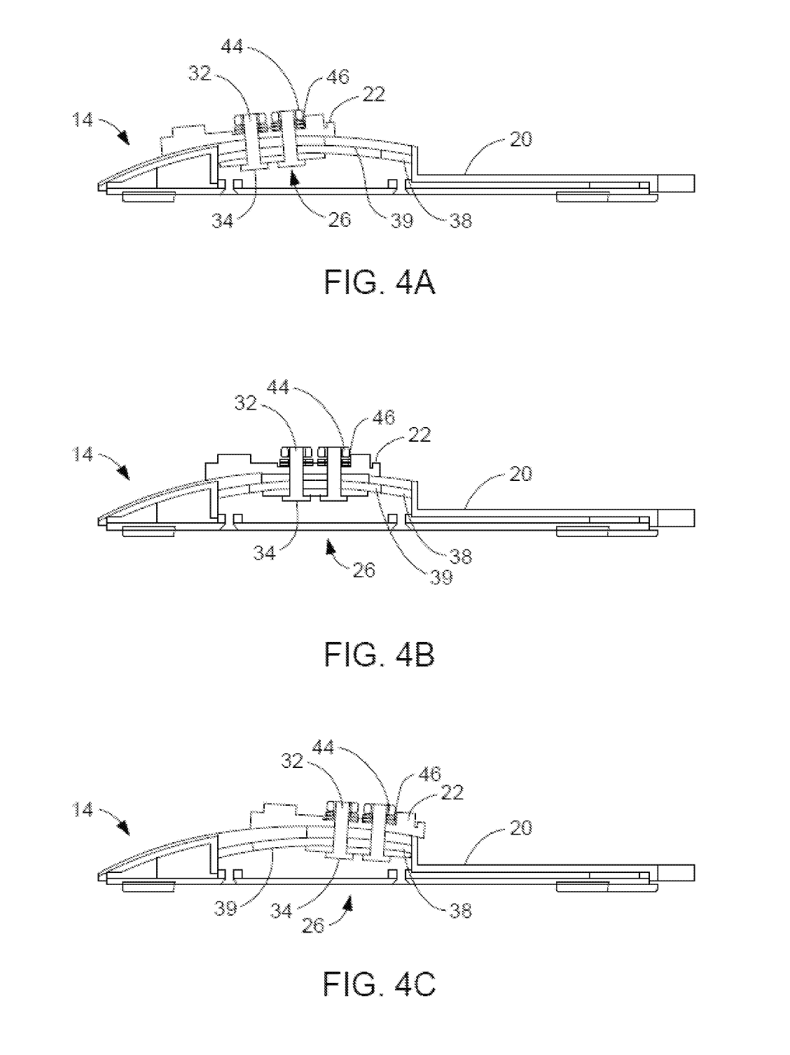

The advantageous tilt and translate movement illustrated in FIG. 3A, FIG. 3B, and FIG. 3C is further illustrated in FIG. 4A, FIG. 4B, and FIG. 4C. The cross-sectional view of tilt assembly 14 illustrated in FIG. 4A is representative of the first position as illustrated in FIG. 3A. Similarly, the cross-sectional view of tilt assembly 14 illustrated in FIG. 4B is representative of the second position as illustrated in FIG. 3B, and the cross-sectional view of tilt assembly 14 illustrated in FIG. 4C is representative of the third position as illustrated in FIG. 3C. As illustrated in FIG. 4A, the anchor assembly 26 is translated forwardly within the base casing 20. This is accomplished by slideable movement imparted by the user grabbing the display screen 12 and pulling the display screen forward relative to the base casing 20. The fasteners 32 are allowed to translate forwardly within channels 39 formed in the retaining block 38. Similarly, as illustrated in FIG. 4B, the anchor assembly 26 is translated rearwardly relative to FIG. 3A within the base casing 20. This may also be accomplished by movement imparted by the user. As illustrated in FIG. 4C, the anchor assembly 26 is translated rearwardly relative to FIG. 3B within the base casing 20. This may also be accomplished by movement imparted by the user.

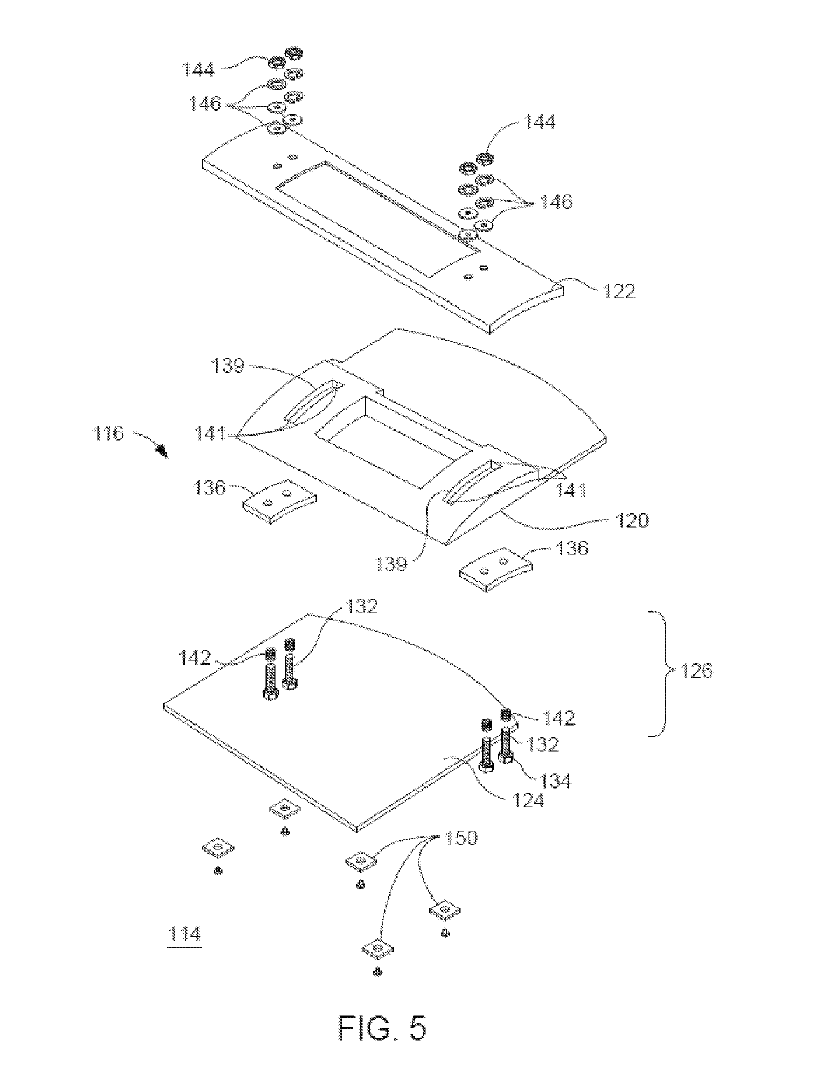

Embodiments of a tilt assembly 114 are illustrated in an exploded view in FIG. 5. Tilt assembly 114 shares many features with tilt assembly 14. The tilt assembly 114 generally includes a base assembly 116. The base assembly 116 includes a base casing 120. A base plate 122 is configured for slideable movement about the base casing 120. A bottom plate 124 is provided for forming the bottom facing surface of the base casing 120 and enclosing an anchor assembly 126. The anchor assembly 126 is configured for extending from within the base casing 120 through tracks 130 defined therein and engaging with base plate 122.

Tracks 130 are configured to receive a fastener 132 that extends therethrough and into slider block 136 and further into the base plate 122. A shoulder 134 formed on the fastener 132 secures the fastener 132 against the base casing 120. One or more springs 142 may be provided to be coaxially aligned with the fastener 132 for providing dampening resistance and improving wear. A releasable fastener such as a nut 144 may be provided on an upward facing surface of the base plate 122 for receiving and engaging with the fastener 132. One or more washers 146 may be provided, and may include belleville or spring washers for further engaging the fastener 132 and providing tensioning forces thereto. One or more pads 150 may be provided on a bottom facing portion of the bottom plate 124 for providing improved traction characteristics with the proximal surface. Slider block 136 may be made from a polymer having sufficient strength, yet low friction such as polyoxymethylene.

The tracks 130 may include one or more materials or characteristics for providing a resistance to the fastener 132 as the fastener 132 approaches either terminal end of the channel 139. In this manner, the tracks 130 may include, for example, resilient material 141 at an end thereof. Resilient material 141 may be a felt-like or other textile-based material, a polymer-based material, a spring or other biasing material, or the like. In this manner, material 141 may be provided for limiting and slowing the translation speed of the display screen 112 as it is translated fore and aft to the terminal positions of the track 130.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A tilt assembly for a display screen, the tilt assembly comprising:
a base assembly including a base casing configured to engage with a proximally positioned surface and a base plate configured to cooperatively form the tilt assembly with the base casing, the base casing defining a convex upper facing surface and the base plate configured to translate aft and fore about the casing to impart a pivot to the display screen in a convex arcuate direction relative to the base casing.

2. The tilt assembly of claim 1, wherein the tilt assembly comprises an anchor assembly extending into a corresponding track defined in the base casing, the anchor assembly being slideable about the base.

3. The tilt assembly of claim 2, wherein the anchor assembly comprises a fastener that defines a shoulder to engage with a bottom facing surface of the track.

4. The tilt assembly of claim 3, wherein one or more springs are provided about the fastener to provide support during movement of the display screen.

5. The tilt assembly of claim 3, wherein the fastener extends through the base casing and base plate.

6. The tilt assembly of claim 1, further including one or more slider assemblies against which the fastener engages.

7. A tilt assembly for use with a display screen, the tilt assembly comprising:
a base assembly including a base casing configured to engage with a proximally positioned surface and a base plate configured to cooperatively form the tilt assembly with the base casing, the tilt assembly defining a pivot point beneath the base assembly.

8. The tilt assembly of claim 7, wherein the pivot point is defined below the proximally positioned surface.

9. (canceled)

10. The tilt assembly of claim 9, wherein the base casing and base plate each define a generally arcuate engagement surface, the base plate being slideably engaged with the base casing and carrying the display screen.

11. The tilt assembly of claim 10, wherein the display screen is aft and fore translatable about the base casing, and further wherein, aft and fore translation of the display screen imparts a tilt angle to the display screen.

12. The tilt assembly of claim 7, wherein the tilt assembly comprises an anchor assembly extending into a corresponding track defined in the base, the anchor assembly being slideable about the base.

13. The tilt assembly of claim 12, wherein the anchor assembly comprises a fastener that defines a shoulder to engage with a bottom facing surface of the track.

14. The tilt assembly of claim 13, wherein one or more springs are provided about the fastener to provide support during movement of the display screen.

15. The tilt assembly of claim 14, wherein the fastener extends through the base casing and base plate.

16. The tilt assembly of claim 7, further including one or more slider assemblies against which the fastener engages.

17. A tilt assembly for use with a display screen, the tilt assembly comprising:
a base assembly configured to engage with a proximally positioned surface that carries the display screen and defining one or more aft and fore extending arcuate tracks that receive an anchor assembly extending from a base casing to a base plate that cooperatively forms a tilt assembly, the base casing defining a convex upper facing surface and and the tilt assembly being configured to provide translation of the display screen that generally corresponds to the arcuate shape of the tracks, wherein the tracks define a resilient material at each end thereof to provide dampening forces when the display screen is positioned at an end portion of the tracks.

18. The tilt assembly of claim 17, wherein the resilient material is a high friction material.

19. The tilt assembly of claim 17, wherein the resilient material is a biasing material.

20. (canceled)

21. The tilt assembly of claim 20, wherein the display screen is aft and fore translatable about the base casing, and further wherein, aft and fore translation of the display screen imparts a tilt angle to the display screen.

22. A display screen assembly comprising:
a display screen; and
a base assembly including a base casing configured to engage with a proximally positioned surface and a base plate configured to cooperatively form a tilt assembly with the base casing and to carry the display screen, the base casing defining a convex upper facing surface and the base plate configured to translate aft and fore movement relative to the base casing that imparts a pivot to the display screen.

23. The display screen assembly of claim 22, wherein the tilt assembly defines a pivot point beneath the base assembly.

24. The display screen assembly of claim 22, wherein the pivot point is defined below the proximally positioned surface.

25. The display screen assembly of claim 22, wherein the base assembly defines one or more aft and fore extending convex tracks that receive an anchor assembly extending from a base cover to the base plate that cooperatively forms the tilt assembly, the tilt assembly being configured to provide translation of the display screen that generally corresponds to the convex shape of the tracks, wherein the tracks define a resilient material at each end thereof to provide dampening forces when the display screen is positioned so as to be at an end portion of the tracks.
